(19) United States
(12) Patent Application Publication
(10) Pub. No.: US 2004/0251510 A1
(43) Pub. Date: Dec. 16, 2004

(54) Package structure of an image sensor module

(76) Inventors: Irving You, Hsinchu Hsien (TW); Hsiu Wen Tu, Hsinchu Hsien (TW); Jichen Wu, Hsinchu Hsien (TW); Jason Chang, Hsinchu Hsien (TW); Figo Hsieh, Hsinchu Hsien (TW)

Correspondence Address: PRO-TECHTOR INTERNATIONAL, 20775 Norada Court, Saratoga, CA, 95070-3018, US

(21) Appl. No.: 10/458,942

(22) Filed: Jun. 10, 2003

(51) Int. Cl. H01L 31/0203

(52) U.S. Cl. 257/433

(57) ABSTRACT

A package structure of an image sensor module for electrically connecting to a printed circuit board includes a transparent layer, an image sensing chip, a lens holder and a lens barrel. A plurality of signal input terminals and signal output terminals are formed on the transparent layer. The electrical circuits are formed on the image sensing chip, each of the electrical circuits is formed with bonding pads and is electrically connected to the transparent layer by way of flip chip bonding. A lens holder is formed with a through hole, an internal thread is formed on an inner wall of the through hole. The lens holder is mounted to the upper surface of the transparent layer. A lens barrel is arranged within the through hole of the lens holder and is formed with an external thread, which is screwed to the internal thread of the lens holder, the lens barrel is formed with a chamber and an opening communicating with the chamber.

### BACKGROUND OF THE INVENTION

1. Field of the Invention

The present invention relates to a package structure of an image sensor module, in particular, to a package structure of an image sensor module, which is formed by way of flip chip bonding and capable of simplifying the manufacturing processes and lowering the manufacturing costs.

2. Description of the Related Art

A general sensor is used for sensing signals, which may be optical or audio signals. The sensor of the invention is used for receiving image signals and transforming the image signals into electrical signals, which are transmitted to a printed circuit board.

Referring to FIG. 1, a conventional image sensor module includes a substrate 10, a spacer 18, an image sensing chip 22, a transparent glass 28, a lens holder11 and a lens barrel13.

The substrate 10 is made of ceramic materials. A plurality of signal input terminals 12 and signal output terminals 14 are formed on the periphery of the substrate 10. The signal output terminals 14 are used for electrically connecting the substrate 10 to a printed circuit board 16.

The spacer 18 is arranged on the substrate 10 to form a chamber 20 togather with the substrate 10.

The image sensing chip 22 is mounted on the substrate 10 and is within the chamber 20 surrounded by the substrate 10 and the spacer 18. The substrate 10 is electrically connected to the image sensing chip 22 by a plurality of wirings 24 that electrically connects the bonding pads 26 of the image sensing chip 22 to the signal input terminals 12 of the substrate 10, respectively.

The transparent glass 28 is mounted on the spacer 18, so that the image sensing chip 22 can be protected and may be received image or optical signals travelling through the transparent glass 28. The image signals are then transformed into electrical signals, which is to be transmitted to the signal input terminals 12 of the substrate 10. The electrical signals are transmitted from the signal input terminals 12 of the substrate 10 to the signal output terminals 14, and then, from the signal output terminals 14 to the printed circuit board 16.

The lens holder11 is formed with a through hole15, an internal thread 17 is formed on an inner wall of the through hole15, the lens holder33 is mounted to the transparent layer28.

The lens barrel13 is arranged within the through hole15 of the lens holder11 and is formed with an external thread19, which is screwed to the internal thread 17 of the lens holder11, the lens barrel3 is formed with a chamber21 and an opening23 communicating with the chamber21; and an aspheric lens25 is placed within the chamber58.

The above-mentioned package structure of the image sensor module has a lot of elements and has a lot of complicated manufacturing processes. Moreover, since the substrate 10 is made of ceramic materials, the manufacturing costs are high. Furthermore, since the ceramic materials cannot be easily cut, the substrates 10 must to be manufactured one by one, which also increases the manufacturing costs.

To solve the above-mentioned problems, it is necessary for the inventor to provide a package structure of an image sensor module, in order to facilitate the manufacturing processes and to lower the manufacturing costs.

### SUMMARY OF THE INVENTION

It is therefore an object of the present invention to provide a package structure of an image sensor module capable of reducing the number of package elements and lowering the package costs.

It is therefore another object of the present invention to provide a package structure of an image sensor module, which is capable of simplifying and facilitating the manufacturing processes.

To achieve the above-mentioned objects, the present invention is characterized in that the image sensing chip is directly packaged under the transparent layer by way of flip chip bonding. Thus, the substrate for signal transmission is no longer needed.

According to one aspect of the present invention, a package structure of an image sensor module for electrically connecting to a printed circuit board includes a transparent layer, an image sensing chip, a lens holder and a lens barrel. A plurality of signal input terminals and signal output terminals are formed on the transparent layer. The signal output terminals are used for electrically connecting the transparent layer to the printed circuit board. Electrical circuits are formed on the image sensing chip. Each of the electrical circuits is formed with bonding pads and is electrically connected to the transparent layer by way of flip chip bonding. The bonding pads are electrically connected to the signal input terminals of the transparent layer. The image sensing chip receives image signals via the transparent layer, converts the image signals into electrical signals, and transmits the electrical signals from the signal output terminals of the transparent layer to the printed circuit board. A lens holder is formed with a through hole, an internal thread is formed on an inner wall of the through hole, the lens holder is mounted to the upper surface of the transparent layer. A lens barrel is arranged within the through hole of the lens holder and is formed with an external thread, which is screwed to the internal thread of the lens holder, the lens barrel is formed with a chamber and an opening communicating with the chamber; and a spherical lens is placed within the chamber.

Thus, the packaging costs of the image sensor module can be lowered and the packaging processes of the image sensor can be simplified.

### BRIEF DESCRIPTION OF THE DRAWINGS

FIG. 1 is a cross-sectional view showing a conventional package structure of an image sensor module.

FIG. 2 is a cross-sectional view showing a package structure of an image sensor module in accordance with the present invention.

FIG. 3 is an embodiment showing a package structure of the image sensor module in accordance with present the invention.

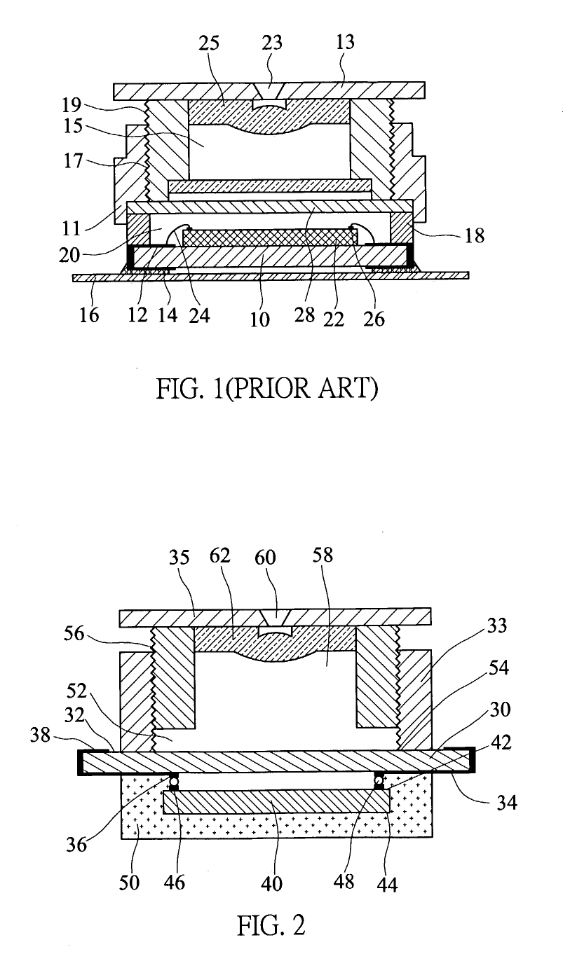

### DETAIL DESCRIPTION OF THE INVENTION

Referring to FIG. 2, a package structure of an image sensor module of the present invention includes a transparent layer 30, an image sensing chip 40, a lens holder33, a lens barrel 35 and a glue layer 50.

The transparent layer 30 may be a transparent glass, which has an upper surface 32 and a lower surface 34. A plurality of signal input terminals 36 are formed on the lower surface 34 by way of wire plating. Also, a plurality of signal output terminals 38 are formed on the upper surface 32. The signal input terminals 36 extend from the periphery of the lower surface 34 of the transparent layer 30 to the upper surface 32 so as to electrically connect to the signal output terminals 38.

The image sensing chip 40 has an first surface 42 and a second surface 44. Electrical circuits are formed on the upper surface 42. Each of the electrical circuits is formed with bonding pads 46 that are electrically connected to the transparent layer 30 by way of flip chip bonding. Thus, the bonding pads 46 are electrically connected to the signal input terminals 36 formed on the lower surface 32 of the transparent layer 30. At this time, the image sensing chip 40 can receive image signals via the transparent layer 30. Then, the image signals are converted into electrical signals and transmitted to the signal input terminals 36 of the transparent layer 30.

Furthermore, a plurality of gold bumps 48 are formed on each of the bonding pads 46 of the image sensing chip 40. Thus, the image sensing chip 40 can be electrically connected to the signal input terminals 36 of the transparent layer 30, and the image sensing chip 40 can be adhered to the transparent layer 30 by an adhesive glue layer.

A lens holder33 is formed with a through hole52, an internal thread 54 is formed on an inner wall of the through hole52. The lens holder33 is mounted to the upper surface32 of the transparent layer30.

A lens barrel35 is arranged within the through hole52 of the lens holder33 and is formed with an external thread56, which is screwed to the internal thread 52 of the lens holder33, the lens barrel35 is formed with a chamber58 and an opening60 communicating with the chamber58; and an aspheric lens62 placed within the chamber58.

A glue layer50 are filled in the electrical connecting portion between the image sensing chip 40 and transparent layer 30 so as to protect the image sensing chip 40 and the transparent layer 30. Alternatively, the transparent layer 30 also can be firmly adhered onto the image sensing chip 40.

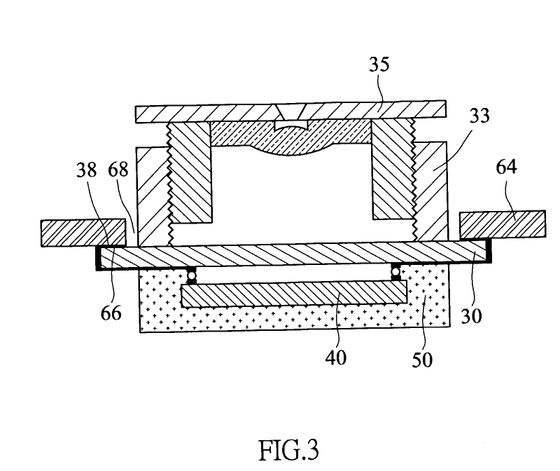

Referring to FIG. 3, the package structure of an image sensor module of the present invention will be described. First, a printed circuit board 64, on which a plurality of electrical circuits (not shown) are formed, is provided, each of the electrical circuits is formed with contact points 66 and a slot 68 in the central portion of the printed circuit board.

The signal output terminals 38 are formed on the upper surface 34 of the transparent layer 30 are electrically connected to the contact points 66 of the printed circuit board 64, respectively, after the image sensor package is packaged. The transparent layer 30 is located under the slot 68. Thus, the image sensing chip 40 can receive the image signals travelling from the slot 68 and penetrating the transparent layer 30, convert the image signals into electrical signals, and transmit the electrical signals to the signal input terminals 36 on the transparent layer 30. The electrical signals can be transmitted from the signal input terminals 36 and the signal output terminals 38 to the printed circuit board 64.

As a result, the package structure has the following advantages.

1. Since the transparent layer 30 is used as the signal transmission medium for the image sensing chip 40, the substrate 10 in the prior art can be omitted, and the packaging costs can also be lowered.

2. Since the substrate 10 can be omitted, the package volume can be made thin, small, and light.

3. Since the image sensing chip 40 is directly electrically connected to the transparent layer 30 by way of flip chip bonding, the manufacturing processes can be simplified, and the manufacturing costs also can be lowered.

While the present invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A package structure of an image sensor module for electrically connecting to a printed circuit board, comprising
a transparent layer on which a plurality of signal input terminals and signal output terminals are formed, the signal output terminals being used for electrically connecting the transparent layer to the printed circuit board; and
an image sensing chip on which a plurality of electrical circuits are formed, each of the electrical circuits being formed with bonding pads and being electrically connected to the transparent layer by way of flip chip bonding, wherein the bonding pads are electrically connected to the signal input terminals of the transparent layer, and the image sensing chip receives image signals via the transparent layer, converts the image signals into electrical signals, and transmits the electrical signals from the signal output terminals of the transparent layer to the printed circuit board;
a lens holder formed with a through hole, an internal thread being formed on an inner wall of the through hole, the lens holder being mounted to the upper surface of the transparent layer; and
a lens barrel arranged within the through hole of the lens holder and is formed with an external thread, which is screwed to the internal thread of the lens holder, the lens barrel being formed with a chamber and an opening communicating with the chamber; and an aspheric lens placed within the chamber.

2. The package structure of an image sensor module according to claim 1, wherein the transparent layer is a transparent glass.

3. The package structure of an image sensor module according to claim 1, wherein the transparent layer comprises a upper surface formed with the signal output terminals, and a lower surface opposite to the upper surface and formed with the signal input terminals.

4. The package structure of an image sensor module according to claim 1, wherein the signal input terminals and the signal output terminals are formed on the transparent layer by way of wire plating.

5. The package structure of an image sensor module according to claim 1, wherein a slot is formed in the printed circuit board, and the transparent layer is arranged in the slot of the printed circuit board so that the image signals are transmitted to the image sensing chip via the transparent layer.

6. The package structure of an image sensor module according to claim 1, wherein a glue layer is provided at electrical connecting portion between the image sensing chip and the transparent layer.

7. The package structure of an image sensor according to claim 1, wherein after the image sensing chip is electrically connected to the transparent layer, a glue layer is provided to seal the electrical connecting portion between the image sensing chip and the transparent layer.
